(19) United States
(12) Patent Application Publication
(10) Pub. No.: US 2023/0403955 A1
(43) Pub. Date: Dec. 14, 2023

(54) SEMICONDUCTOR MEMORY DEVICE

(71) Applicant: Kioxia Corporation, Tokyo (JP)

(72) Inventors: Ryouji MASUDA, Yokkaichi Mie (JP); Hiroki TOKUHIRA, Kawasaki Kanagawa (JP)

(73) Assignee: Kioxia Corporation, Tokyo (JP)

(21) Appl. No.: 18/330,515

(22) Filed: Jun. 7, 2023

(30) Foreign Application Priority Data
Jun. 10, 2022 (JP) 2022-094031

(51) Int. Cl. H10N 70/00; H10B 63/10; H10B 63/00; H10N 70/20

(52) U.S. Cl. CPC H10N 70/8616; H10B 63/10; H10B 63/20; H10B 63/80; H10N 70/231; H10N 70/8413; H10N 70/8828; H10N 70/063

(57) ABSTRACT

A semiconductor memory device includes: a first wiring extending in a first direction; a second wiring extending in a second direction that intersects with the first direction; a resistance change film provided between the first wiring and the second wiring and including at least one element selected from a group consisting of germanium, antimony, and tellurium; an electrode provided between the resistance change film and the first wiring; and a first film selectively provided between the electrode and the first wiring, in which the electrode includes a surface in contact with both of the first wiring and the first film.

### CROSS-REFERENCE TO RELATED APPLICATION

This application is based upon and claims the benefit of priority from Japanese Patent Application No. 2022-094031, filed Jun. 10, 2022, the entire contents of which are incorporated herein by reference.

### FIELD

Embodiments described herein relate generally to a semiconductor memory device.

### BACKGROUND

A resistive random access memory (ReRAM) using a change in resistance of a film is known. As a type of ReRAM, a phase change memory (PCM) using a change in resistance value depending on thermal phase transition between a crystalline state and an amorphous state in a memory area of a film is developed. A superlattice PCM where two different alloys are repeatedly stacked can induce phase change in a film at a low current, and thus attracts attention as a memory device where power consumption can be easily reduced.

### DESCRIPTION OF THE DRAWINGS

FIG. 1 is a block diagram illustrating a semiconductor memory device according to at least one embodiment;

FIG. 2 is an equivalent circuit diagram illustrating a configuration of a part of a memory cell array;

FIG. 3 is a schematic perspective view illustrating a configuration of a part of the memory cell array;

FIGS. 4A and 4B are cross-sectional views illustrating a configuration of a part of a memory mat according to a first embodiment;

FIGS. 5A and 5B are cross-sectional views illustrating a method of manufacturing a semiconductor memory device according to the first embodiment;

FIGS. 6A and 6B are cross-sectional views illustrating the method of manufacturing the semiconductor memory device according to the first embodiment continued from FIGS. 5A and 5B;

FIGS. 7A and 7B are cross-sectional views illustrating the method of manufacturing the semiconductor memory device according to the first embodiment continued from FIGS. 6A and 6B;

FIGS. 8A and 8B are cross-sectional views illustrating the method of manufacturing the semiconductor memory device according to the first embodiment continued from FIGS. 7A and 7B;

FIGS. 9A and 9B are cross-sectional views illustrating the method of manufacturing the semiconductor memory device according to the first embodiment continued from FIGS. 8A and 8B;

FIGS. 10A and 10B are cross-sectional views illustrating the method of manufacturing the semiconductor memory device according to the first embodiment continued from FIGS. 9A and 9B;

FIGS. 11A and 11B are cross-sectional views illustrating the method of manufacturing the semiconductor memory device according to the first embodiment continued from FIGS. 10A and 10B;

FIGS. 12A and 12B are cross-sectional views illustrating the method of manufacturing the semiconductor memory device according to the first embodiment continued from FIGS. 11A and 11B;

FIGS. 13A and 13B are cross-sectional views illustrating the method of manufacturing the semiconductor memory device according to the first embodiment continued from FIGS. 12A and 12B;

FIGS. 14A and 14B are cross-sectional views illustrating the method of manufacturing the semiconductor memory device according to the first embodiment continued from FIGS. 13A and 13B;

FIGS. 15A and 15B are cross-sectional views illustrating the method of manufacturing the semiconductor memory device according to the first embodiment continued from FIGS. 14A and 14B;

FIGS. 16A and 16B are cross-sectional views illustrating the method of manufacturing the semiconductor memory device according to the first embodiment continued from FIGS. 15A and 15B;

FIGS. 17A and 17B are cross-sectional views illustrating the method of manufacturing the semiconductor memory device according to the first embodiment continued from FIGS. 16A and 16B;

FIGS. 18A and 18B are cross-sectional views illustrating a configuration of a part of a memory mat according to a second embodiment;

FIGS. 19A and 19B are cross-sectional views illustrating a method of manufacturing the semiconductor memory device according to the second embodiment continued from FIGS. 10A and 10B;

FIGS. 20A and 20B are cross-sectional views illustrating the method of manufacturing the semiconductor memory device according to the second embodiment continued from FIGS. 19A and 19B;

FIGS. 21A and 21B are cross-sectional views illustrating the method of manufacturing the semiconductor memory device according to the second embodiment continued from FIGS. 20A and 20B;

FIGS. 22A and 22B are cross-sectional views illustrating the method of manufacturing the semiconductor memory device according to the second embodiment continued from FIGS. 21A and 21B;

FIGS. 23A and 23B are cross-sectional views illustrating a method of manufacturing the semiconductor memory device according to the second embodiment continued from FIGS. 22A and 22B;

FIGS. 24A and 24B are cross-sectional views illustrating the method of manufacturing the semiconductor memory device according to the second embodiment continued from FIGS. 23A and 23B;

FIGS. 25A and 25B are cross-sectional views illustrating the method of manufacturing the semiconductor memory device according to the second embodiment continued from FIGS. 24A and 24B; and

FIGS. 26A and 26B are cross-sectional views illustrating the method of manufacturing the semiconductor memory device according to the second embodiment continued from FIGS. 25A and 25B.

### DETAILED DESCRIPTION

Embodiments provide a semiconductor memory device capable of reducing heat radiation during an operation of a memory cell to reduce an operating current.

In general, according to at least one embodiment, a semiconductor memory device includes: a first wiring extending in a first direction; a second wiring extending in a second direction that intersects with the first direction; a resistance change film provided between the first wiring and the second wiring and including at least one element selected from a group consisting of germanium, antimony, and tellurium; an electrode provided between the resistance change film and the first wiring; and a first film selectively provided between the electrode and the first wiring, in which the electrode includes a surface in contact with both of the first wiring and the first film.

Hereinafter, embodiments will be described with reference to the drawings. In the following description of the drawings, the same or equivalent components will be represented by the same or equivalent reference numerals. It should be noted that the drawings are schematic, and a relationship and the like between the thickness and planar dimensions are different from the real ones.

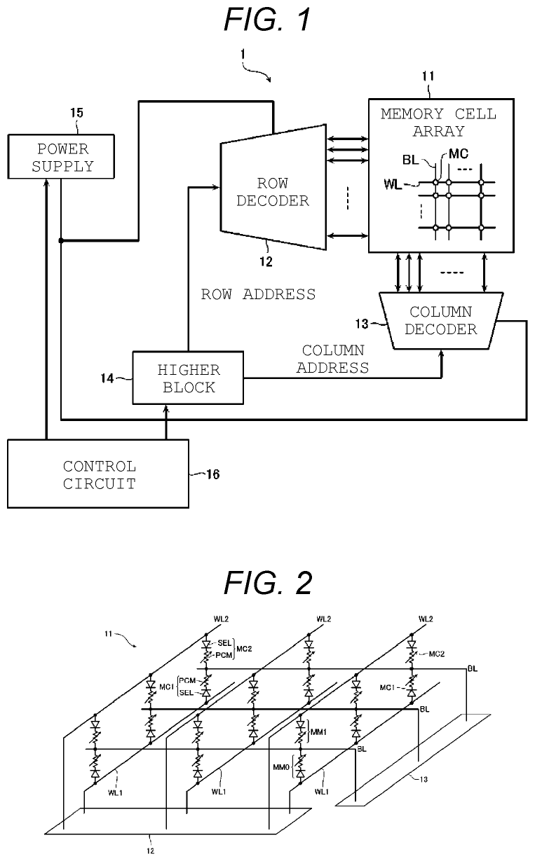

FIG. 1 is a block diagram illustrating a semiconductor memory device according to at least one embodiment.

The semiconductor memory device 1 according to at least one embodiment includes: a memory cell array 11; a row decoder 12 and a column decoder 13 that select a desired memory cell MC from the memory cell array 11; a higher block decoder 14 that assigns a row address and a column address to the decoders 12 and 13; a power supply 15 that supplies power to each of the units of the semiconductor memory device 1; and a control circuit 16 that controls the units of the semiconductor memory device 1.

The memory cell array 11 includes a plurality of memory cells MC each of which stores data of one bit or a plurality of bits. The memory cell array 11 applies a predetermined voltage to a desired bit line BL and a desired word line WL selected by the row decoder 12 and the column decoder 13 such that the desired memory cell MC is accessible (data erasing/writing/reading).

FIG. 2 is an equivalent circuit diagram illustrating a configuration of a part of the memory cell array 11.

The memory cell array 11 includes a plurality of bit lines BL, a plurality of word lines WL1 and WL2, and a plurality of memory cells MC1 and MC2 connected to the bit lines BL and the word lines WL1 and WL2.

The memory cells MC1 and MC2 are connected to the row decoder 12 through the word lines WL1 and WL2, and are connected to the column decoder 13 through the bit lines BL. Each of the memory cells MC1 and MC2 stores, for example, data corresponding to one bit. The plurality of memory cells MC1 and MC2 connected to the common word lines WL1 and WL2 store, for example, data corresponding to one page.

Each of the memory cells MC1 and MC2 is configured by a series circuit including a phase change film PCM and a selector SEL. The phase change film PCM acquires two types of states including a low-resistance crystalline state and a high-resistance amorphous state according to a current pattern (heating pattern), and thus functions as a resistance change film. By associating the two types of states of the resistance values with information “0” and “1”, the phase change film PCM can function as a memory cell. The selector SEL of the memory cells MC1 and MC2 functions as a rectifier element. Accordingly, current does not substantially flow through the word lines WL1 and WL2 other than the selected word lines WL1 and WL2.

Hereinafter, a configuration including a plurality of bit lines BL, a plurality of word lines WL1, and a plurality of memory cells MC1 corresponding to a first layer of the memory cell array 11 is called a memory mat MM0. Likewise, a configuration including a plurality of bit lines BL, a plurality of word lines WL2, and a plurality of memory cells MC2 corresponding to a second layer of the memory cell array 11 is called a memory mat MM1.

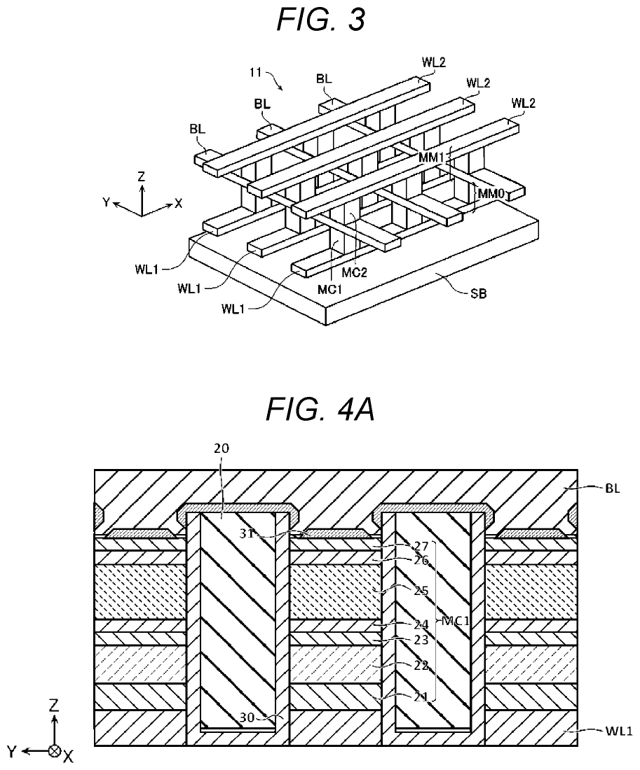

FIG. 3 is a schematic perspective view illustrating a configuration of a part of the memory cell array 11. As illustrated in FIG. 3, the memory cell array 11 includes, for example, a silicon substrate SB, word lines WL, bit lines BL, and memory cells MC.

Next, an X direction, a Y direction, and a Z direction are defined. The X direction and the Y direction are directions along a surface of the silicon substrate SB. The X direction is a direction in which the word line WL extends. The Y direction is a direction that intersects with (for example, perpendicular to) the X direction. The Y direction is a direction in which the bit line BL extends. The Z direction is a direction that intersects with (for example, perpendicular to) the X direction and the Y direction. The Z direction is a thickness direction of the silicon substrate SB. The X direction is an example of “first direction”. The Y direction is an example of “second direction”. The Z direction is an example of “third direction”.

In the example, the memory cell array 11 is a so-called cross-point memory cell array. That is, a plurality of word lines WL1 are provided above the semiconductor substrate SB, the word lines WL1 being disposed at predetermined intervals in the Y direction parallel to an upper surface of the semiconductor substrate SB and extending parallel to the X direction that is parallel to the upper surface of the semiconductor substrate SB and intersects with the Y direction. Above the plurality of word lines WL1, a plurality of bit lines BL are provided, the bit lines BL being disposed at predetermined intervals in the X direction and extending parallel to the Y direction. Above the plurality of bit lines BL, a plurality of word lines WL2 are provided, the word lines WL2 being disposed at predetermined intervals in the Y direction and extending parallel to the X direction.

Memory cells MC1 are provided at each of intersections between the plurality of word lines WL1 and the plurality of bit lines BL.

Likewise, memory cells MC2 are provided at each of intersections between the plurality of bit lines BL and the plurality of word lines WL2. In the example, the memory cells MC1 and MC2 have prismatic shapes, but may have columnar shapes.

### First Embodiment

FIGS. 4A and 4B are cross-sectional views illustrating a configuration of the memory mat MM0 according to a first embodiment. FIG. 4A is a cross-section perpendicular to the X direction, and FIG. 4B is a cross-section perpendicular to the Y direction. The memory mat MM0 includes: the word line WL1 extending in the X direction; the bit line BL extending in the Y direction that faces the word line WL1; the memory cell MC1 disposed between the word line WL1 and the bit line BL; and an insulating layer 20 provided between side surfaces of the plurality of memory cells MC1 in the X direction and the Y direction. The bit line is an example of “first wiring”. The word line WL1 is an example of “second wiring”.

The memory cell MC1 includes a lower electrode layer 21, a selector layer 22 (selector SEL), an intermediate electrode layer 23, a barrier metal layer 24, a resistance change film 25, a barrier metal layer 26, and an upper electrode layer 27 that are stacked in order in the Z direction intersecting with the X direction and the Y direction from the word line WL1 side toward the bit line BL side. An insulating layer 30 is formed on side surfaces of the memory cell MC1 in the X direction and the Y direction, on an upper surface of the word line WL1 and a side surface thereof in the Y direction, and on a side surface of the bit line BL in the X direction. An insulating film 31 is formed on apart of an upper surface of the upper electrode layer 27 and apart of upper surfaces and side surfaces of the insulating layer and the insulating layer 30. The insulating film 31 is an example of “first film”. The lower electrode layer 21 is an example of “first electrode”. The intermediate electrode layer 23 is an example of “second electrode”. The upper electrode layer 27 is an example of “electrode” and “third electrode”.

The word line WL1, the bit line BL, the lower electrode layer 21, the intermediate electrode layer 23, and the upper electrode layer 27 are formed of a conductive material such as tungsten (W), titanium (Ti), or poly-Si. To heat the resistance change film 25, the electrode layers 21, 23, and 27 may be formed of a material having a high heat resistance effect such as carbon nitride (CN). The barrier metal layer 24 is formed between the intermediate electrode layer 23 and the resistance change film and the barrier metal layer 26 is formed between the upper electrode layer 27 and the resistance change film 25. The barrier metal layers 24 and 26 are formed of, for example, a conductive material such as tungsten nitride (WN), titanium nitride (TiN), tantalum (Ta), or tantalum nitride (TaN). The selector layer 22 is formed of, for example, a non-ohmic element including at least one chalcogen, at least one chalcogenide, or at least one element selected from a group consisting of B, Al, Ga, In, C, Si, Ge, Sn, As, P, and Sb or is formed of a non-ohmic element such as a pin diode consisting of a p-type semiconductor, an intrinsic semiconductor layer, and an n-type semiconductor layer. The insulating layer 20 is formed of, for example, an insulator such as silicon oxide (SiO₂) or silicon nitride (Si₃N₄). The insulating layer 30 is formed of, for example, an insulator such as silicon oxide (SiO₂) or silicon nitride (Si₃N₄). The insulating film 31 is formed of, for example, an insulator such as silicon oxide (SiO₂) or silicon nitride (Si₃N₄).

The resistance change film 25 includes chalcogen. Chalcogen is an element belonging to group 16 in the periodic table. The resistance change film 25 includes, for example, sulfur (S), selenium (Se), or tellurium (Te) other than oxygen (O) among chalcogens. The resistance change film 25 may also be a chalcogenide film. Chalcogenide is a compound including chalcogen such as GeSbTe, GeTe, SbTe, or SiTe. That is, the resistance change film 25 may include at least one element selected from a group consisting of germanium, antimony, and tellurium.

Next, a function of the insulating film 31 and an effect of the embodiment will be described. The resistance change film 25 enters an amorphous state (reset state) by heating to a melting temperature or higher and quick cooling. The resistance change film 25 enters a crystalline state (set state) by being heated at a temperature lower than the melting temperature and higher than a crystallization temperature and being slowly cooled. A high operating current is required for heating the resistance change film 25 to the melting temperature or higher to enter the reset state from the set state. By reducing heat radiation from the resistance change film during heating operation, the heating of the resistance change film can be efficiently performed, and the operating current can be reduced. In the embodiment, as illustrated in FIGS. 4A and 4B, a part of the upper surface of the upper electrode layer 27 is covered with the insulating film 31. With such structure, heat radiation from the insulating film 31 can be reduced. Therefore, the operating current can be reduced as compared to a structure where the insulating film 31 is not provided and most of the upper surface of the upper electrode layer 27 is in contact with the bit line BL structure.

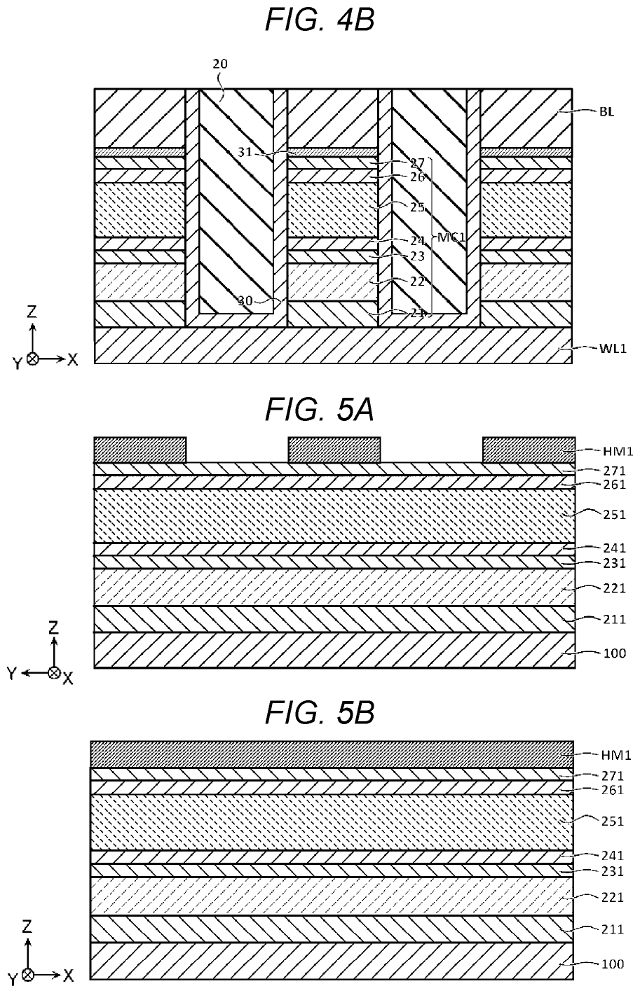

Next, a method of manufacturing the semiconductor memory device according to the first embodiment will be described using FIGS. 5A to 18B. FIG. 5A is a cross-sectional view of a YZ plane illustrating a step of forming a stacked structure in the method of manufacturing the semiconductor memory device according to the first embodiment. FIG. 5B is a cross-sectional view of an XZ plane illustrating a step of forming the stacked structure in the method of manufacturing the semiconductor memory device according to the first embodiment.

As illustrated in FIGS. 5A and 5B, a stacked structure is formed including a conductive layer 100 forming the word line WL1, a conductive layer 211 forming the lower electrode layer 21, a semiconductor layer 221 forming the selector layer 22, a conductive layer 231 forming the intermediate electrode layer 23, a conductive layer 241 forming the barrier metal layer 24, a resistance change film 251 forming the resistance change film 25, a conductive layer 261 forming the barrier metal layer 26, and a conductive layer 271 forming the upper electrode layer 27. Each of the layers is sequentially formed using a method such as atomic layer deposition (ALD) or chemical vapor deposition (CVD). A hard mask HM1 is formed on the conductive layer 271 by lithography.

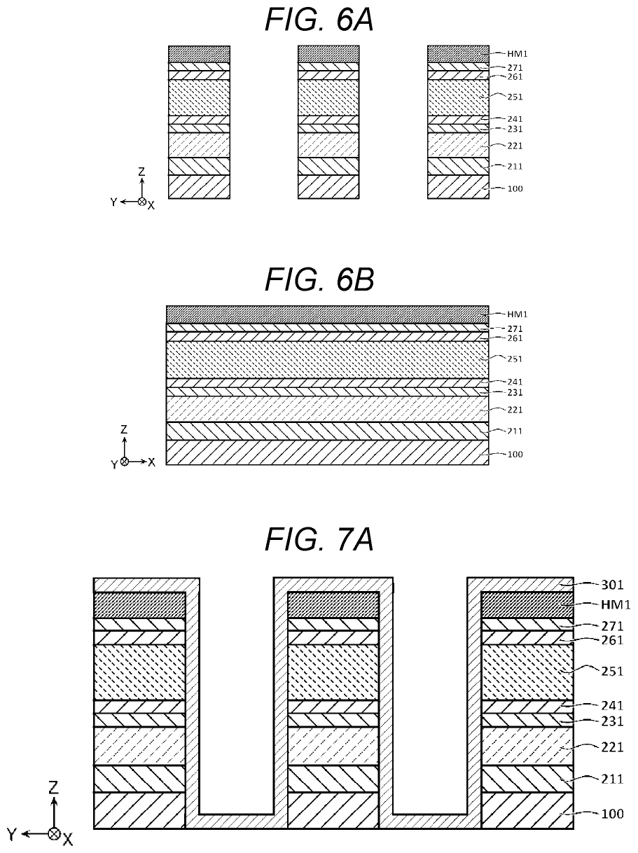

As illustrated in FIGS. 6A and 6B, a part of the stacked structure ranging from the conductive layer 271 to the conductive layer 100 in the Z direction is removed, for example, by anisotropic etching such as reactive ion etching (RIE). The stacked structure is divided in the Y direction by being selectively etched using the linear hard mask HM1 that extends in the X direction.

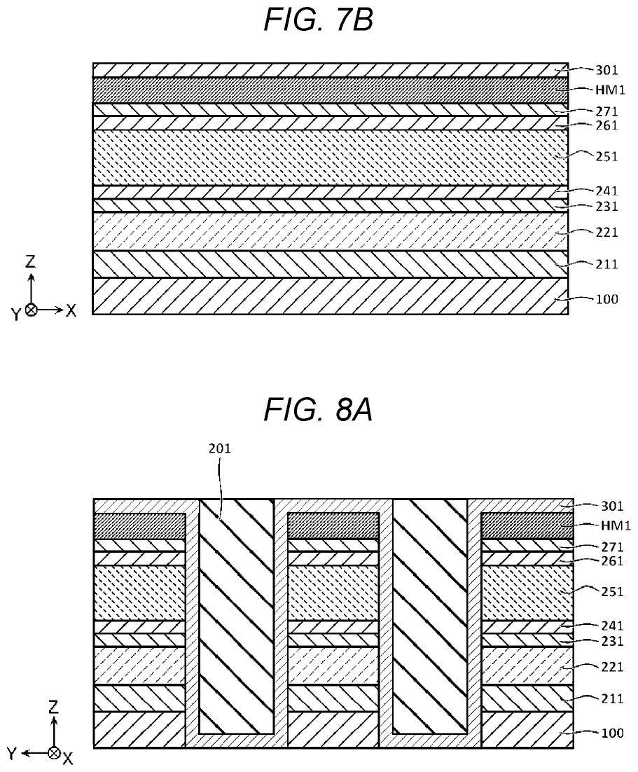

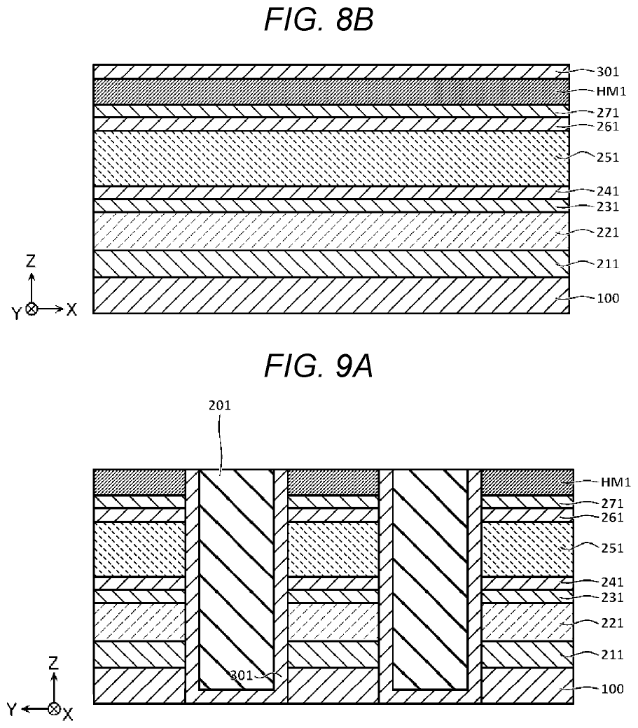

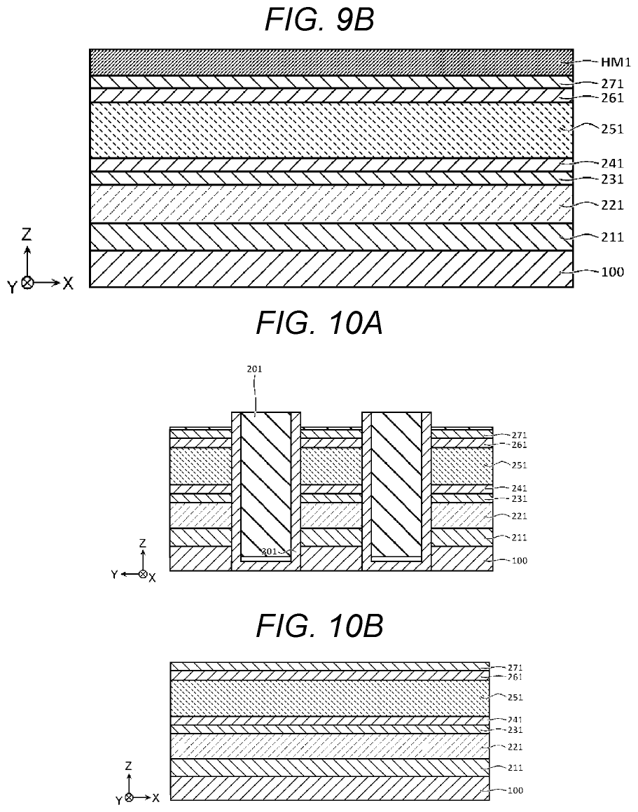

Next, as illustrated in FIGS. 7A and 7B, an insulating layer 301 covers the stacked structure. Next, as illustrated in FIGS. 8A and 8B, an insulating layer 201 is embedded in each of the parts of the stacked structure divided by etching. As illustrated in FIGS. 9A and 9B, the upper surface of the insulating layer 301 and the insulating layer 201 are cut by chemical mechanical polishing (CMP) or the like to expose an upper surface of the hard mask HM1.

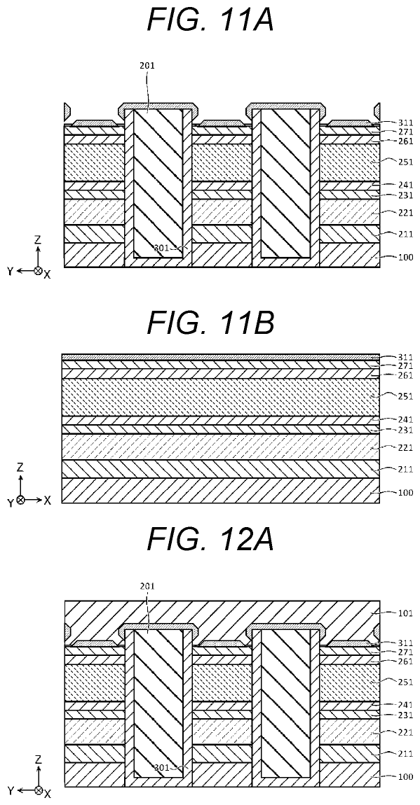

Next, as illustrated in FIGS. 10A and 10B, the hard mask HM1 is removed by etching. Next, as illustrated in FIGS. 11A and 11B, an insulating film 311 is formed on an upper surface of the conductive layer 271, an upper surface of the insulating layer and an upper surface and a side surface of the insulating layer 301. Here, by impairing the coverage of the insulating film 311 to be formed, the insulating film 311 is not formed at a corner portion formed by the conductive layer 271 and the insulating layer 301.

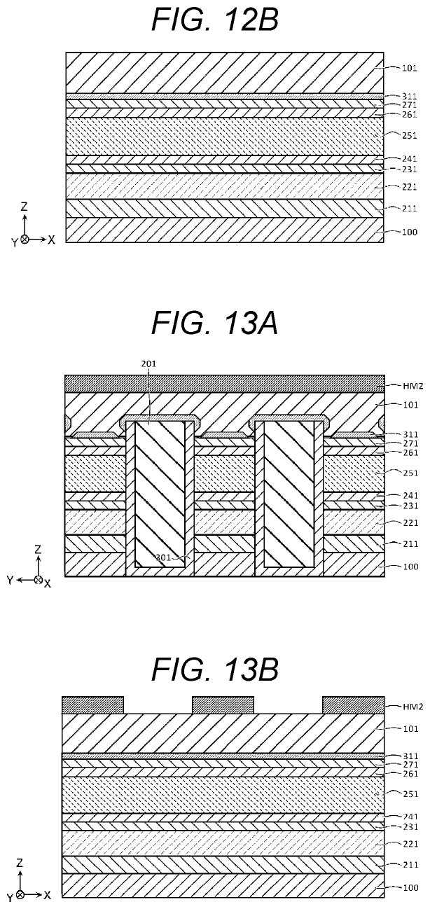

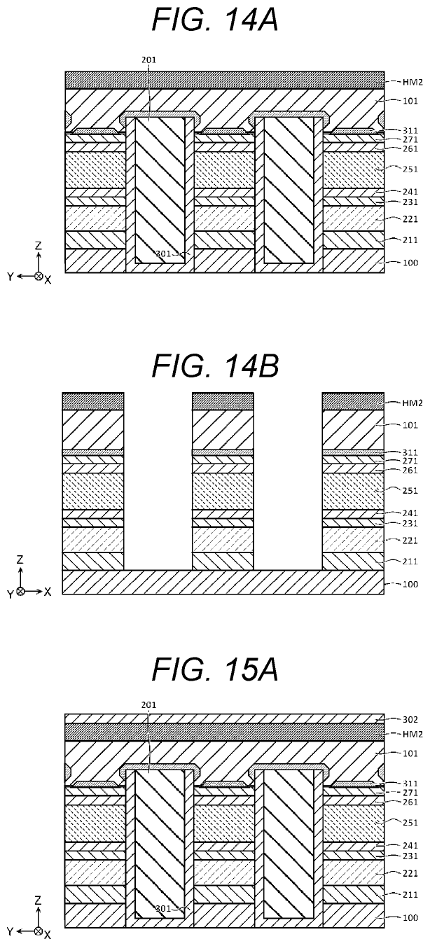

Next, as illustrated in FIGS. 12A and 12B, a conductive layer 101 forming the bit line BL is formed on the insulating film 311. Next, as illustrated in FIGS. 13A and 13B, a hard mask HM2 is formed on the conductive layer 101. As illustrated in FIGS. 14A and 14B, a part of the stacked structure ranging from the bit line BL to the conductive layer 211 in the Z direction is removed, for example, by anisotropic etching such as reactive ion etching (RIE). The stacked structure is divided in the X direction by being selectively etched using the linear hard mask HM2 that extends in the Y direction. In the area where the stacked structure is removed, a part of the conductive layer 100 is exposed.

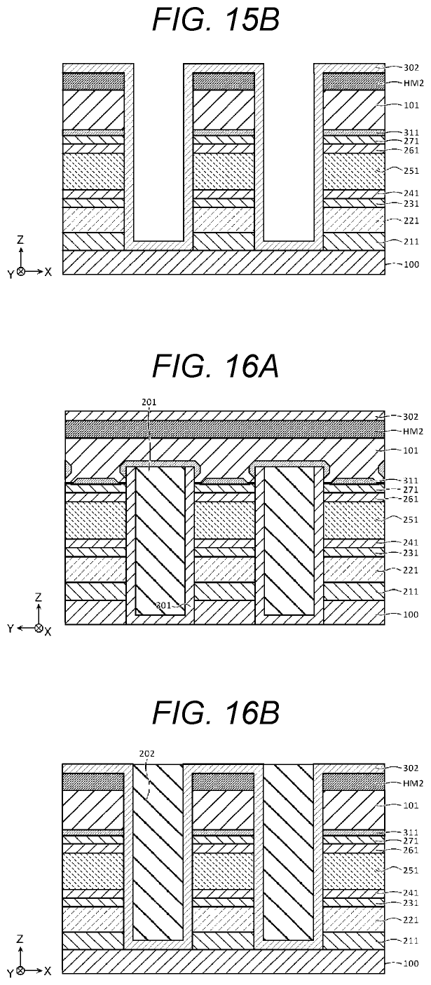

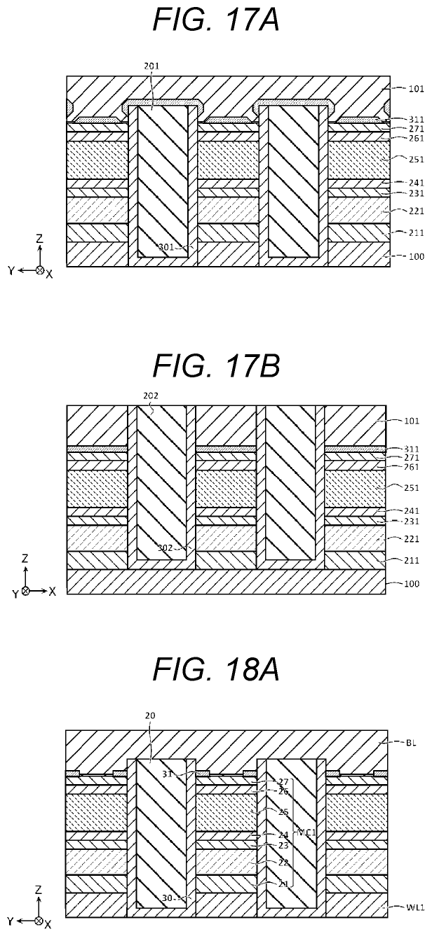

Next, as illustrated in FIGS. 15A and 15B, an insulating layer 302 is formed to cover the stacked structure. Next, as illustrated in FIGS. 16A and 16B, an insulating layer 202 is embedded in each of the parts of the stacked structure divided by etching. As illustrated in FIGS. 17A and 17B, a part of the insulating layer 302, a part of the insulating layer 202, and the hard mask HM2 are cut by chemical mechanical polishing (CMP) or the like to expose an upper surface of the conductive layer 101. Using the above-described method, the semiconductor memory device according to the first embodiment can be manufactured.

### Second Embodiment

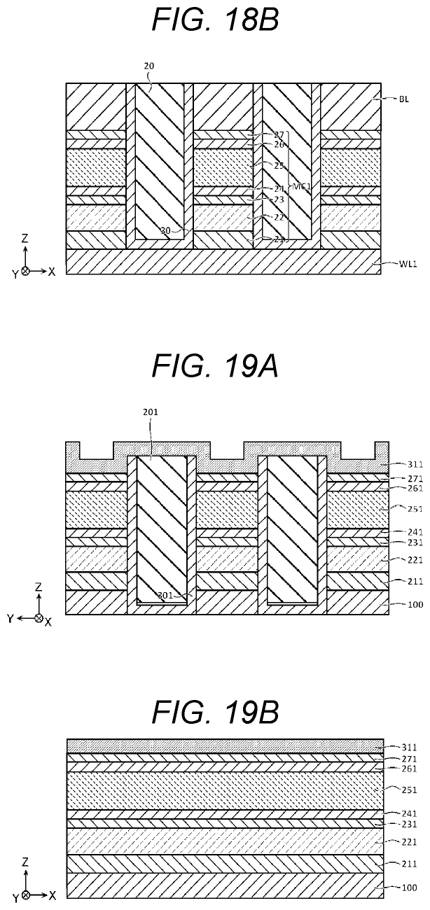

FIGS. 18A and 18B are cross-sectional views illustrating a configuration of the memory mat MM0 according to a second embodiment. FIG. 18A is a cross-section perpendicular to the X direction, and FIG. 18B is a cross-section perpendicular to the Y direction. The semiconductor memory device according to the second embodiment is the same as the semiconductor memory device according to the first embodiment, except that the shape of the insulating film 31 is different. Therefore, the description of common portions will be omitted.

As illustrated in FIGS. 18A and 18B, the memory mat MM0 includes: the word line WL1 extending in the X direction; the bit line BL extending in the Y direction that faces the word line WL1; the memory cells MC1 disposed between the word line WL1 and the bit line BL; and the insulating layer 20 provided between side surfaces of the plurality of memory cells MC1 in the X direction and the Y direction. The insulating layer 30 is formed on side surfaces of the memory cell MC1 in the X direction and the Y direction, on an upper surface of the word line WL1 and a side surface thereof in the Y direction, and on a side surface of the bit line BL in the X direction.

As illustrated in FIG. 18A, the insulating film 31 is formed on a part of the upper surface of the upper electrode layer 27. More specifically, the insulating film 31 is formed at a portion of the upper electrode layer 27 close to the insulating layer 20 other than a center portion of the upper electrode layer 27. With such configuration, heat radiation from the insulating film 31 can be reduced as in the semiconductor memory device according to the first embodiment. Therefore, the operating current can be reduced as compared to a structure where the insulating film 31 is not provided and most of the upper surface of the upper electrode layer 27 is in contact with the bit line BL structure.

Next, a method of manufacturing the semiconductor memory device according to the second embodiment will be described. In the method of manufacturing the semiconductor memory device according to the second embodiment, the same steps as those of the method of manufacturing the semiconductor memory device according to the first embodiment illustrated in FIGS. 5A to 10B can be performed. Therefore, the description of the same steps will be omitted. The method of manufacturing the semiconductor memory device according to the second embodiment continued from FIGS. 10A and 10B will be described using FIGS. 19A to 26B.

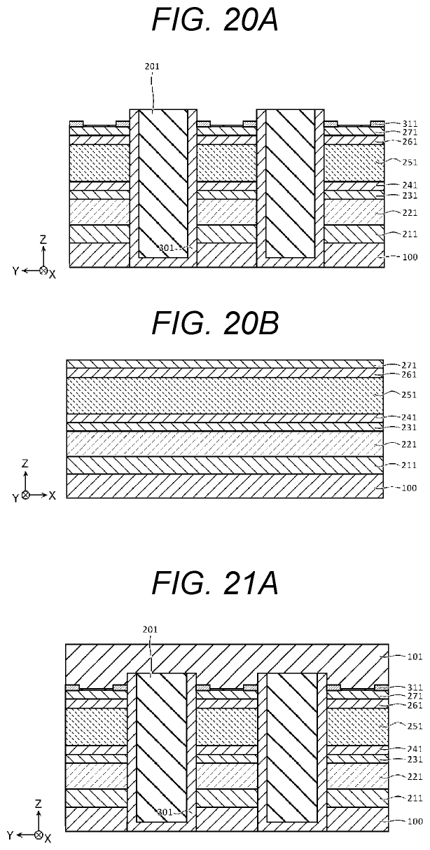

First, as illustrated in FIGS. 19A and 19B, the insulating film 311 is formed on an upper surface of the conductive layer 271, an upper surface of the insulating layer 20, and an upper surface and a side surface of the insulating layer 301. Next, for example, anisotropic etching such as reactive ion etching (RIE) is performed. As a result, as illustrated in FIGS. 20A and 20B, the insulating film 31 is formed on a part of the upper surface of the upper electrode layer 27.

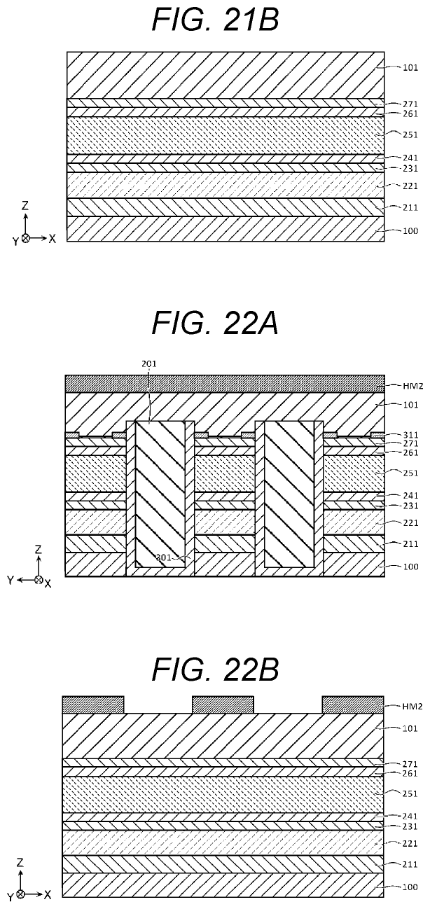

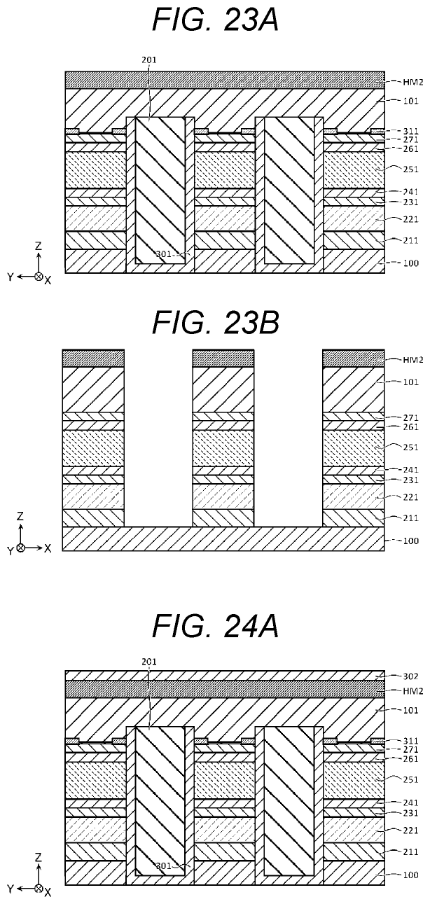

Next, as illustrated in FIGS. 21A and 21B, the conductive layer 101 forming the bit line BL is formed on the insulating film 311. Next, as illustrated in FIGS. 22A and 22B, the hard mask HM2 is formed on the conductive layer 101. As illustrated in FIGS. 23A and 23B, a part of the stacked structure ranging from the bit line BL to the conductive layer 211 in the Z direction is removed, for example, by anisotropic etching such as reactive ion etching (RIE). The stacked structure is divided in the X direction by being selectively etched using the linear hard mask HM2 that extends in the Y direction. In the area where the stacked structure is removed, a part of the conductive layer 100 is exposed.

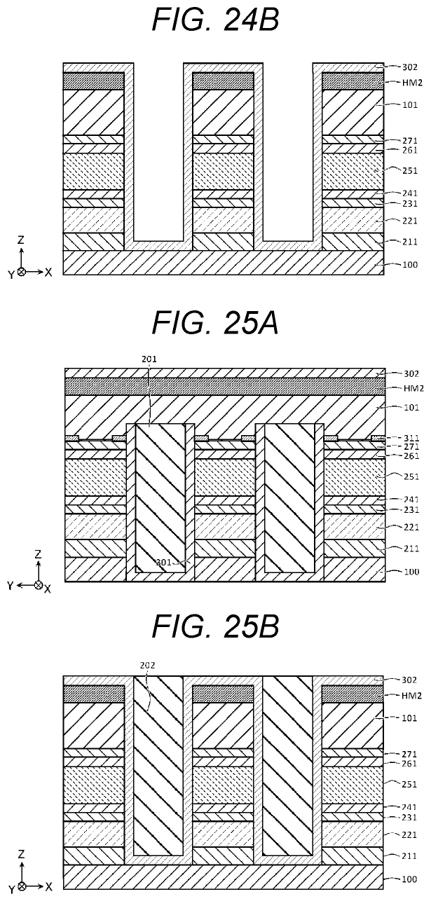

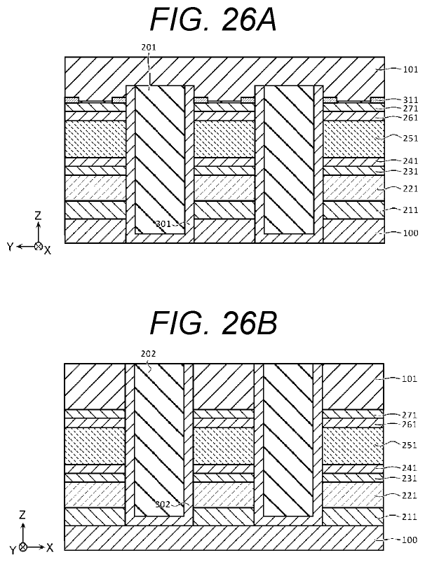

Next, as illustrated in FIGS. 24A and 24B, the insulating layer 302 covers the stacked structure. Next, as illustrated in FIGS. 25A and 25B, the insulating layer 202 is formed to be embedded in each of the parts of the stacked structure divided by etching. As illustrated in FIGS. 26A and 26B, a part of the insulating layer 302, a part of the insulating layer 202, and the hard mask HM2 are cut by chemical mechanical polishing (CMP) or the like to expose the upper surface of the conductive layer 101. Using the above-described method, the semiconductor memory device according to the second embodiment can be manufactured.

In the first embodiment and the second embodiment, the insulating film 31 that is the first film is self-aligned on the protrusion portion of the insulating layer around the columnar memory cell. In other words, an area of the upper electrode layer in contact with the first wiring and an area of the upper electrode in contact with the first film are self-aligned with the memory cell, that is, the pattern of the upper electrode. However, the present disclosure is not limited thereto.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a first wiring extending in a first direction;
a second wiring extending in a second direction, the second direction intersecting with the first direction;
a resistance change film disposed between the first wiring and the second wiring and including at least one element selected from the group consisting of germanium, antimony, and tellurium;
an electrode disposed between the resistance change film and the first wiring; and
a first film selectively disposed between the electrode and the first wiring, wherein
the electrode including a surface in contact with both of the first wiring and the first film.

2. The semiconductor memory device according to claim 1, wherein
a center portion of the surface of the electrode is in contact with the first film.

3. The semiconductor memory device according to claim 1, wherein
a center portion of the surface of the electrode is in contact with the first wiring.

4. The semiconductor memory device according to claim 1, wherein
an area of the electrode in contact with the first wiring and an area of the electrode in contact with the first film are self-aligned with a pattern of the electrode.

5. The semiconductor memory device according to claim 1, wherein
a thermal conductivity of the first film is lower than a thermal conductivity of the first wiring.

6. The semiconductor memory device according to claim 1, wherein
the first film is an insulating film.

7. A semiconductor memory device comprising:
a first wiring extending in a first direction;
a second wiring extending in a second direction, the second direction intersecting with the first direction;
a first electrode, a second electrode, and a third electrode disposed between the first wiring and the second wiring and facing each other in a third direction, the third direction intersects with the first direction and the second direction;
a selector layer disposed between the first electrode and the second electrode;
a resistance change film disposed between the second electrode and the third electrode; and
an insulating film disposed between the third electrode and the first wiring, wherein
the third electrode includes a surface in contact with both of the first wiring and the insulating film.

8. The semiconductor memory device according to claim 7, further comprising a barrier metal layer between the second electrode and the resistance change film and between the third electrode and the resistance change film.

9. The semiconductor memory device according to claim 1, wherein the resistance change film has an amorphous state or a crystalline state depending on a temperature of the resistance change film.

10. The semiconductor memory device according to claim 6, wherein the insulation film includes silicon oxide or silicon nitride.

11. The semiconductor memory device according to claim 7, wherein the selector layer is a non-ohmic element.

12. The semiconductor memory device according to claim 11, wherein the non-ohmic element is a chalcogen or a chalcogenide.

13. The semiconductor memory device according to claim 8, wherein the barrier metal layer includes one of WN, TiN, Ta or TaN.
